(19) United States
(12) Patent Application Publication
(10) Pub. No.: US 2025/0085349 A1
(43) Pub. Date: Mar. 13, 2025

(54) INTEGRATED HARDWARE-IN-THE-LOOP (HIL) SYSTEM FOR TESTING HARDWARE DEVICES AND A METHOD THEREOF

(71) Applicant: L&T TECHNOLOGY SERVICES LIMITED, Chennai (IN)

(72) Inventors: AYYAMPERUMAL NARAYANASAMY, Kallakurichi (IN); HARSHITHA DINESH, Mysore (IN)

(21) Appl. No.: 18/811,919

(22) Filed: Aug. 22, 2024

(30) Foreign Application Priority Data
Sep. 7, 2023 (IN) 202341060346

(51) Int. Cl. G01R 31/319; G01R 31/3183

(52) U.S. Cl. CPC G01R 31/31917; G01R 31/318307

(57) ABSTRACT

Disclosed herein is an integrated Hardware-in-the-Loop (HIL) system and a method for testing hardware devices. In an embodiment, system comprises a front panel which may be configured to perform one or more predefined Input/Output (I/O) operations. Further, system comprises a rear panel interfaced with the front panel which may be configured to connect to a Device Under Test (DUT). Furthermore, the system comprises a microcontroller unit configured with an automated test application interface which further comprises a plurality of hardware abstraction layers required for testing hardware devices, wherein the hardware devices may include devices of invariant domain and invariant version.

### TECHNICAL FIELD

The present subject matter is, in general, related to testing of a device, but not exclusively, to an integrated Hardware-in-the-loop (HIL) system and a method for testing hardware devices.

### BACKGROUND

Hardware-in-the loop (HIL) testing is a technique used for testing and validation of embedded systems wherein several hardware devices are tested using one or more test simulators. In general, each functionality of the hardware device is tested using different simulators that comprise a combination of hardware components. This testing technique requires different software test applications for each different simulators for testing different functionalities of hardware device and different types of hardware devices.

Most of the existing solutions are designed to address specific scenarios. For example, in some of the existing approaches, validation and testing of hardware devices are performed using a PC based simulator without a common software for validating hardware devices. Similarly, in other existing approaches, testing is performed which includes validating a single functionality of a hardware device at a single duration of time. However, there are some drawbacks to these approaches.

Firstly, the existing approaches do not contain a common software application for testing all the functionalities of a hardware device. Secondly, the existing approaches do not perform testing of multiple hardware devices at a time. Further, the existing approaches do not focus on interoperability of different component testing. Moreover, the existing approaches do not perform the testing of hardware devices of different versions and domains.

The information disclosed in this background of the disclosure section is only for enhancement of understanding of the general background of the disclosure and should not be taken as an acknowledgement or any form of suggestion that this information forms the prior art already known to a person skilled in the art.

### SUMMARY

Disclosed embodiments herein relate to an integrated Hardware-in-the-loop (HIL) system and a method for testing a hardware device. The system comprises a front panel which may be configured to perform one or more predefined Input/Output (I/O) operations. Further, the system comprises a rear panel interfaced with the front panel which may be configured to connect to a Device Under Test (DUT). Furthermore, the system comprises a microcontroller unit configured with an automated test application interface. The automated test application interface comprises a plurality of hardware abstraction layers required for testing the DUT. The microcontroller unit may be configured to receive test parameters required for testing the DUT through the front panel. Further the microcontroller unit decodes the test parameters for determining a test functionality to be performed on the DUT. Furthermore, the microcontroller unit performs the test functionality on the DUT using one of the plurality of hardware abstraction layers corresponding to the test parameters and generates a test outcome corresponding to the test functionality. Finally, the microcontroller unit outputs the test outcome on the display interface of the front panel of the system.

Further, the present disclosure relates to a method of testing hardware devices using an integrated HIL system. The method comprises receiving by a microcontroller unit of the integrated HIL system, test parameters required for testing a Device Under Test (DUT) through a front panel of the system. Further, the method comprises decoding by the microcontroller unit, the test parameters for determining a test functionality to be performed on the DUT. Furthermore, the method comprises performing by the microcontroller unit, the test functionality on the DUT and generating a test outcome corresponding to the test functionality. Finally, the method comprises outputting by the microcontroller unit, the test outcome on a display interface of the front panel.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 illustrates an exemplary architecture overview of an integrated HIL system for testing of a hardware device in accordance with some embodiments of the present disclosure;

FIG. 2A shows a detailed block diagram of the integrated HIL system of FIG. 1 in accordance with some embodiments of the present disclosure;

FIG. 2B is an exemplary illustration to show that the testing is being performed on the plurality of hardware devices simultaneously by the integrated HIL system in accordance with some embodiments of the present disclosure;

FIG. 3 shows an automated test application framework of the integrated HIL system for performing testing functionality on the DUT using plurality of hardware abstraction layers in accordance with some embodiments of the present disclosure;

FIG. 4 shows a flowchart illustrating a method of testing hardware devices using an integrated HIL system in accordance with some embodiments of the present disclosure; and

FIG. 5 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

The present disclosure relates to an integrated Hardware-in-the-Loop (HIL) system and a method for testing hardware devices. In an embodiment, the present disclosure provides a system with software integrated with hardware for testing hardware devices of invariant domains and invariant versions. Also, the present disclosure provides a system for testing multiple hardware devices at a time.

In other words, the present disclosure proposes a method of testing hardware devices using an integrated HIL system. The proposed method comprises receiving by a microcontroller unit of the integrated HIL system, test parameters required for testing a Device Under Test (DUT) through a front panel of the system. Further, the method comprises decoding by the microcontroller unit, the test parameters for determining a test functionality to be performed on the DUT. Upon decoding the test parameters, the microcontroller unit performs the test functionality on the DUT and generates a test outcome corresponding to the test functionality. Later, the microcontroller unit displays the test outcome on the front panel of the integrated HIL system through display interface.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

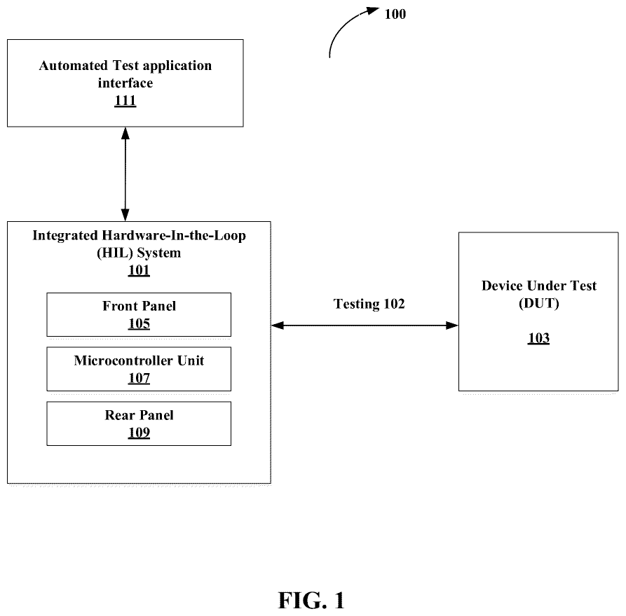

FIG. 1 illustrates an exemplary architecture overview of a system 100 for testing 102 of a hardware device using an integrated HIL system 101 in accordance with some embodiments of the present disclosure.

The system 100 comprises the integrated HIL system 101 and a DUT 103 communicatively connected to and/or interfaced with the integrated HIL system 101. In an example, the DUT 103 may be an Electronic Control Unit (ECU) or a hardware module or a system including one or more ECU's. Alternatively, the DUT 103 may include any other hardware device with testing 102 functionality. The integrated HIL system 101 may be a hardware equipment comprising multiple hardware components which is integrated to interface with an in-built automated test application configured within the integrated HIL system 101.

In an embodiment, the integrated HIL system 101 comprises a front panel 105, a Microcontroller unit (MCU) 107 and a rear panel 109 communicatively coupled with each other. The front panel 105 is configured to perform one or more pre-defined Input/Output (I/O) operations such as receiving user selection input and control commands to perform the test functionality of the DUT 103. In one embodiment, the front panel 105 may be a display unit configured with a Graphical User Interface (GUI) for enabling operating the integrated HIL system 101. The front panel 105 may also be configured with a power socket/a power connector for inputting the power supply to the integrated HIL system 101 to test the DUT 103. The DUT 103 is connected to the integrated HIL system 101 via the rear panel 109. To perform the testing 102 operation, the MCU 107 executes the testing 102 functionality on the DUT 103 via an automated test application interface 111 configured with the MCU 107. In an embodiment, the automated test application interface 111 may be configured to access the automated test application that comprises a plurality of hardware abstraction layers for testing 102 hardware devices.

In operation, the microcontroller unit 107 of the integrated HIL system 101 may receive the test parameters required for testing 102 the DUT 103 through the front panel 105. The test parameters may be decoded by the microcontroller unit 107 for determining the test functionality to be performed on the DUT 103. In an embodiment, the microcontroller unit 107 may generate a test outcome upon performing the test functionality on the DUT 103. Subsequent to generation of test outcome corresponding to the testing 102 functionality, the microcontroller unit 107 may output the test outcome on the display unit of the front panel 105 of the system 101.

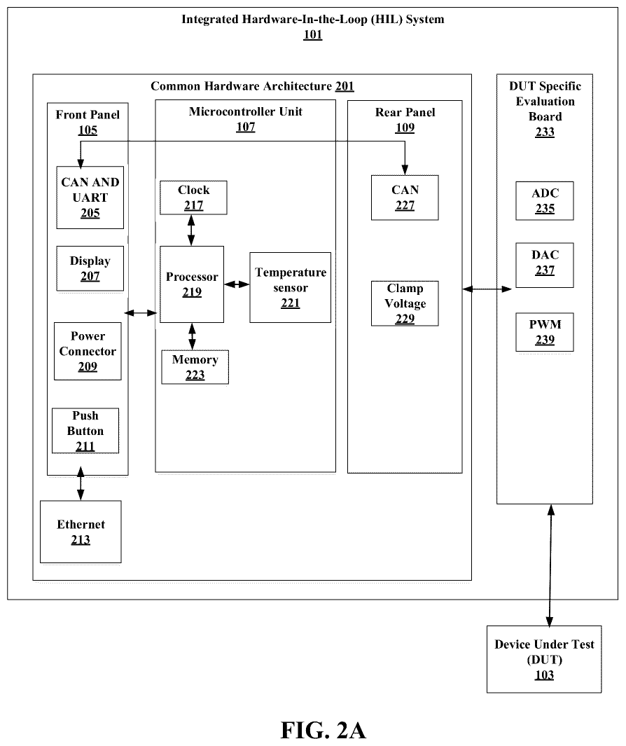

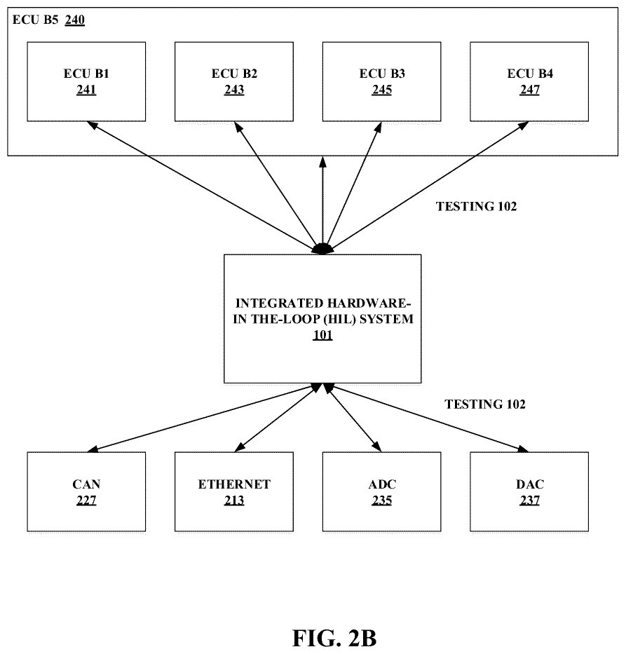

FIG. 2A shows a detailed block diagram of an integrated HIL system 101 in accordance with some embodiments of the present disclosure.

As illustrated, the integrated HIL system 101 comprises a common hardware architecture 201 which may include the front panel 105, the microcontroller unit 107 and the rear panel 109. In some implementations, the front panel 105 may include a Controller Area Network (CAN) and Universal Asynchronous Receiver-Transmitter (UART) module 205 for communicating with the other hardware components of the system 101, a display unit 207 for displaying the test outcome upon testing 102 the functionality of the DUT 103, a Power connector 209 for inputting the power supply and a Push button 211 for turning ON/OFF the integrated HIL system 101. In an embodiment, the integrated HIL system 101 further comprises an Ethernet module 213 for interfacing with the front panel 105 for network connection.

The microcontroller unit 107 comprises a clock 217, a processor 219, a temperature sensor 221 and a memory 223 for executing the testing 102 functionality of the DUT 103. In an embodiment, the clock 217 may determine the processing time for executing the testing 102 functionality of the DUT 103. Further, the processor 219 may execute the functionality of testing 102 on the DUT 103 and the memory 223 may store the executed functionality data. In an embodiment, the temperature sensor 221 may monitor the temperature of the microcontroller unit 107. As an example, the temperature sensors 221 may detect variation of temperature in the range of −55 degree Celsius to 150 degrees Celsius. Furthermore, there may be a temperature alert pin in the temperature sensor 221, which may send a signal to the processor 219 when the temperature of the microcontroller unit 107 crosses the above-mentioned range. Subsequently, the processor 219 may turn off the microcontroller unit 107 until the temperature of the microcontroller unit 107 is within the above-mentioned range.

The rear panel 109 of the integrated HIL system 101 comprises a CAN module 227 for interfacing with the front panel 105 and connecting to the DUT 103. The rear panel 109 further comprises a clamp voltage unit 229. The clamp voltage unit 229 controls an input voltage that can be given to the DUT 103 connected to the integrated HIL system 101. As an example, the input voltage may be 12V, which may be directly fed to the DUT 103. Here, the DUT 103 may be a hardware device of any variant, version, configuration, or domain.

In an embodiment, the integrated HIL system 101 comprises plurality of test modules including at least a DUT specific evaluation board (hereinafter referred to as evaluation board) 233. The evaluation board 233 comprises one or more modules, including but not limited to an Analog-to-Digital Converter (ADC) module 235, a Digital-to-Analog Converter (DAC) module 237 and a Pulse Width Modulation (PWM) module 239 etc. In an embodiment, the ADC module 235 may be used to convert the signal from analog into digital form for better testing 102 of functionality of DUT 103. Further, the DAC module 237 may be used to convert the signal from digital to analog form for better testing 102 of functionality of DUT 103. Similarly, the PWM module 239 may be used for converting the signals into pulses.

FIG. 2B provides an exemplary illustration wherein the testing 102 is performed on the plurality of hardware devices simultaneously by the integrated HIL system 101 in accordance with some embodiments of the present disclosure.

In an embodiment, the integrated HIL system 101 performs the testing 102 of multiple hardware devices or DUTs 103 at a time. In an embodiment, the DUT 103 may be an Electronic Control Unit (ECU) or an ECU system 240 containing one or more ECU's or a test module such as CAN module 227, Ethernet module 213, ADC module 235, DAC module 237 etc.

In an embodiment, the integrated HIL system 101 performs the testing 102 of multiple test modules that DUT 103 supports at the same time and not just one module at a time. For example, the testing 102 functionality can be performed for CAN module 227, Ethernet module 213, ADC module 235, DAC module 237 parallelly at a time.

In an embodiment, the system 240 comprises multiple ECUs such as ECU B1 241, ECU B2 243, ECU B3 245, and ECU B4 247. In one example, the ECU B1 241 may be an ECU of ‘X’ version and the ECU B2 243 may be an ECU of different version ‘Y’ with different testing 102 functionality compared to ECU B1 241 which needs different test simulators for testing 102 different functionality of ECUs. The integrated HIL system 101 may perform the testing 102 of all ECU's irrespective of their versions and domains. Further, the integrated HIL system 101 performs the testing 102 of multiple ECUs at a time of different testing 102 functionality.

In an embodiment, the integrated HIL system 101 performs the testing 102 of hardware devices which comprises a combination of multiple ECU's each with different functionality without relying upon different test simulators for each ECU.

In an embodiment, the integrated HIL system 101 may be configured to integrate with a new hardware for testing 102 in the case of future development in the technology. For example, the integrated HIL system 101 may be seamlessly configured with an Automotive Audio Bus (A2B) module that is used in automotive cars.

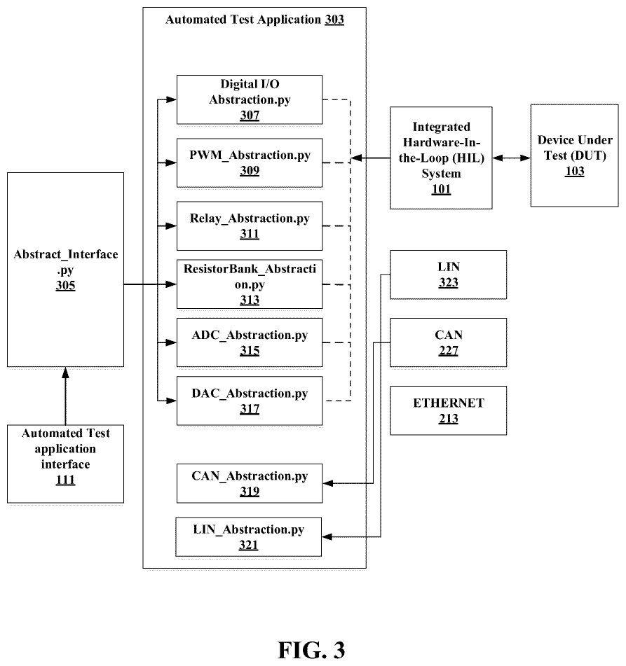

FIG. 3 shows an automated test application framework of the integrated HIL system 101 for performing testing 102 functionality on the DUT 103 using plurality of hardware abstraction layers in accordance with some embodiments of the present disclosure.

In an embodiment, the MCU 107 is configured with an automated test application 303 that comprises a plurality of hardware abstraction layers, wherein the plurality of hardware abstraction layers may communicate with corresponding plurality of test modules through an abstract interface 305 which is configured in the automated test application interface 111.

The hardware abstraction layers may include, but not limited to, a Digital I/O_abstraction.py 307, PWM_Abstraction.py 309, Relay_Abstraction.py 311, ResistorBank_Abstraction.py 313, ADC_Abstraction.py 315, DAC_Abstraction.py 317, CAN_Abstraction.py 319, LIN_Abstraction.py 321. This plurality of hardware abstraction layers communicate with the corresponding test modules such as Local Interconnect Network (LIN) 323, CAN 227, Ethernet 213 etc. using abstract interface 305 which is configured with the automated test application interface 111.

In an embodiment, the hardware abstraction layers are configured with the plurality of test modules of the integrated HIL system 101. These hardware abstraction layers can be modified according to the future requirements for testing 102 the different functionalities of different hardware devices. testing 102.

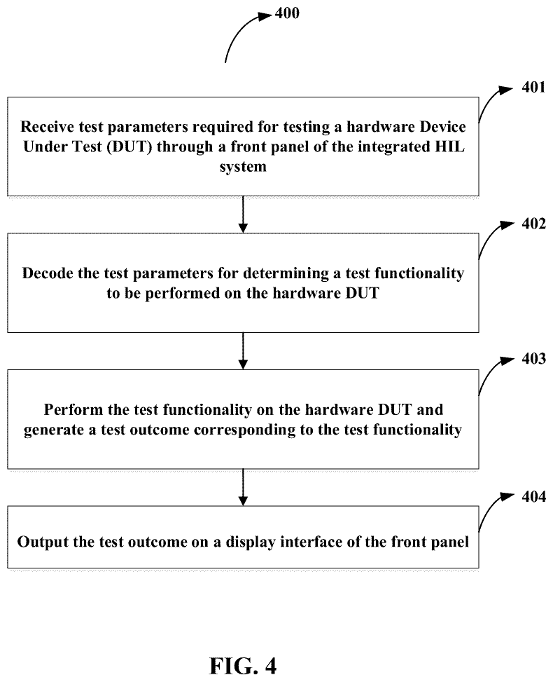

FIG. 4 shows a flowchart illustrating a method 400 of testing 102 hardware devices using an integrated HIL system 101 in accordance with some embodiments of the present disclosure.

At block 401, the method 400 includes receiving by the integrated HIL system 101, test parameters required for testing 102 a Device Under Test (DUT) 103 through a front panel 105 of the integrated HIL system 101.

At block 402, the method 400 includes decoding by the integrated HIL system 101, the test parameters for determining a test functionality to be performed on the DUT 103. In an embodiment, the microcontroller unit 107 of the integrated HIL system 101 is configured with the automated test application interface 111 to receive the test parameters for testing 102 the DUT 103 and decodes the test parameters for determining the test functionality of the DUT 103.

At block 403, the method 400 includes performing by the integrated HIL system 101, the test functionality on the DUT 103 and generating a test outcome corresponding to the test functionality. The hardware abstraction layers communicate with the corresponding test module through abstract interface to perform the testing 102 functionality of the DUT 103.

At block 404, the method 400 includes outputting by the integrated HIL system 101, the test outcome on a display unit 207 of the front panel 105. In an embodiment the test outcome comprises a plurality of log files generated while performing the test functionality and an indication of complete testing 102 of the DUT 103.

### Computer System 101

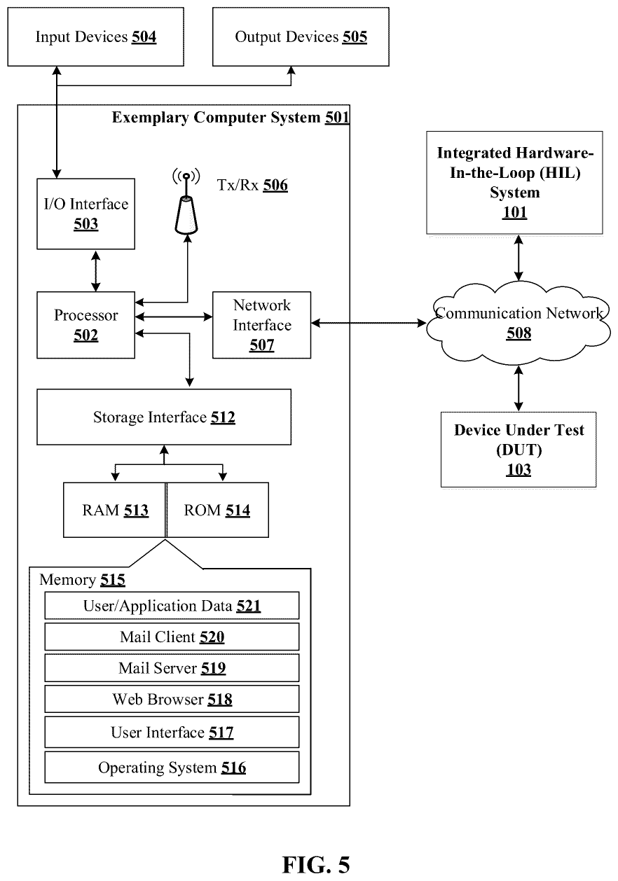

FIG. 5 illustrates a block diagram of an exemplary computer system 501 for implementing embodiments consistent with the present disclosure. In an embodiment, the computer system 501 may be the integrated HIL system 101 illustrated in FIG. 1, which may be used for testing the DUT 103. The computer system 501 may include a central processing unit (“CPU” or “processor”) 502. The processor 502 may comprise at least one data processor for executing program components for executing user- or system generated business processes. A user may include an owner of the DUT 103, an organization or any system/sub-system being operated parallel to the computer system 501. The processor 502 may include specialized processing units such as integrated system (bus) controllers, memory management control units, floating point units, graphics processing units, digital signal processing units, etc.

The processor 502 may be disposed in communication with one or more Input/Output (I/O) devices (504 and 505) via I/O interface 503. In some embodiments, the processor 502 may be disposed in communication with a communication network 508 via a network interface 507. The network interface 507 may communicate with the communication network 508. Using the network interface 508 and the communication network 508, the computer system 501 may connect with the DUT 103 for collecting information related to the DUT 103 and to provide test parameters to the DUT 103.

In an implementation, the communication network 508 may be implemented as one of the several types of networks, such as intranet or Local Area Network (LAN) and such within the organization. The communication network 508 may either be a dedicated network or a shared network, which represents an association of several types of networks that use a variety of protocols. In some embodiments, the processor 502 may be disposed in communication with a memory 515 (e.g., RAM 513, ROM 514, etc. as shown in FIG. 5) via a storage interface 512.

The memory 515 may store a collection of program or database components, including, without limitation, user/application interface 517, an operating system 516, a web browser 518, and the like. In some embodiments, computer system 501 may store user/application data 521, such as the data, variables, records, etc. as described in this disclosure.

The operating system 516 may facilitate resource management and operation of the computer system 501. The user interface 517 may facilitate display, execution, interaction, manipulation, or operation of program components through textual or graphical facilities. For example, the user interface 517 may provide computer interaction interface elements on a display system operatively connected to the computer system 501.

The web browser 518 may be a hypertext viewing application. Secure web browsing may be provided using Secure Hypertext Transport Protocol (HTTPS), Secure Sockets Layer (SSL), Transport Layer Security (TLS), and the like.

### Advantages of the Embodiments of the Present Disclosure are Illustrated Herein

In an embodiment, the present disclosure helps in testing the hardware devices of any functionality without relying upon different simulators for testing different functionalities.

In an embodiment, the proposed method helps in testing the hardware devices according to the user requirements wherein the system contains a package of software and hardware embedded in it. The integrated HIL system 101 can now be utilized to test the hardware devices of invariant versions and invariant domains and common to all functionality testing.

Moreover, the method of present disclosure enhances testing of multiple hardware devices at a time irrespective of which version or domain it belongs.

As stated above, it shall be noted that the integrated HIL system and the method of the present disclosure may be used to overcome various technical problems related to testing of hardware devices. That is, the aforesaid technical advancements and practical applications of the proposed method may be attributed to the aspects of a performing the test functionality upon receiving the test parameters and generating a test outcome as disclosed in steps 3 of the independent claims 1 and 6 of the present disclosure.

In light of the technical advancements provided by the disclosed integrated HIL system and the method, the claimed steps, as discussed above, are not routine, conventional, or well-known aspects in the art, as the claimed steps provide the aforesaid solutions to the technical problems existing in the conventional technologies. Further, the claimed steps clearly bring an improvement in the functioning of the system itself, as the claimed steps provide a technical solution to a technical problem.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

### REFERRAL NUMERALS

| Reference Number | Description |
|---|---|
| 101 | Integrated Hardware-in-the-loop (HIL) system |
| 102 | Testing |
| 103 | Device Under Test (DUT) |
| 105 | Front Panel |
| 107 | Microcontroller Unit |
| 109 | Rear Panel |
| 111 | Automated test application interface |
| 201 | Common Hardware Architecture |
| 205 | CAN and UART module |
| 207 | Display unit |
| 209 | Power Connector |
| 211 | Push Button |
| 213 | Ethernet Module |
| 217 | Clock |
| 219 | Processor |
| 221 | Temperature sensor |
| 223 | Memory |
| 227 | Controller Area Network (CAN) module |
| 229 | Clamp Voltage Unit |
| 233 | DUT Specific Evaluation Board |
| 235 | Analog to Digital Converter (ADC) module |
| 237 | Digital to Analog Converter (DAC) module |
| 239 | Pulse Width Modulation (PWM) module |
| 240 | ECU B5 |
| 241 | ECU B1 |
| 243 | ECU B2 |
| 245 | ECU B3 |
| 247 | ECU B4 |
| 303 | Automated Test Application |
| 305 | Abstract Interface |
| 307 | Digital I/O Abstraction.py |
| 309 | PWM_Abstraction.py |
| 311 | Relay_Abstraction.py |
| 313 | ResistorBank_Abstraction.py |
| 315 | ADC_Abstraction.py |
| 317 | DAC_Abstraction.py |
| 319 | CAN_Abstraction.py |
| 321 | LIN_Abstraction.py |
| 323 | Local Interconnect Network (LIN) module |
| 501 | Exemplary computer system |
| 503 | I/O Interface of the exemplary computer system |
| 502 | Processor of the exemplary computer system |
| 507 | Network interface |
| 512 | Storage interface |
| 515 | Memory of the exemplary computer system |
| 517 | User/Application interface |
| 516 | Operating system |
| 518 | Web browser |
| 508 | Communication network |
| 504 | Input devices |
| 505 | Output devices |
| 513 | RAM |
| 514 | ROM |

What is claimed is:

1. An integrated Hardware-In-the-Loop (HIL) system for testing hardware devices, the integrated HIL system comprising:
a front panel configured to perform one or more predefined Input/Output (I/O) operations;
a rear panel interfaced with the front panel and configured to connect to a Device Under Test (DUT); and
a microcontroller unit configured with an automated test application interface, wherein the automated test application interface comprises a plurality of hardware abstraction layers required for testing the DUT, wherein the microcontroller unit is configured to:
receive test parameters required for testing the DUT through the front panel;
decode the test parameters for determining a test functionality to be performed on the DUT;
perform the test functionality on the DUT using one of the plurality of hardware abstraction layers corresponding to the test parameters and generate a test outcome corresponding to the test functionality; and
output the test outcome on a display interface of the front panel.

2. The integrated HIL system of claim 1, further comprising a plurality of test modules including at least one of a DUT-specific evaluation board, an ethernet module, a Controller Area Network (CAN) module, an Analog-to-Digital Converter (ADC) module, a Digital-to-Analog Converter (DAC) module, a Pulse Width Modulation (PWM) module, a resistor bank module, Local Interconnect Network (LIN) module, a relay module and a digital I/O module.

3. The integrated HIL system of claim 1, wherein the plurality of hardware abstraction layers of the automated test application interface is configured to correspond to the plurality of test modules.

4. The integrated HIL system of claim 3, wherein the plurality of hardware abstraction layers communicates with corresponding plurality of test modules through an abstract interface configured in the automated test application interface.

5. The integrated HIL system of claim 1, wherein the test outcome comprises a plurality of log files generated while performing the test functionality and an indication of completion of testing of the DUT.

6. The integrated HIL system of claim 1, wherein the rear panel is configured to connect to a plurality of hardware devices of invariant domains and invariant versions for performing a simultaneous testing of each of the plurality of hardware devices.

7. A method of testing hardware devices using an integrated Hardware-In-the-Loop (HIL) system, the method comprising:
receiving, by a microcontroller unit of the integrated HIL system, test parameters required for testing a Device Under Test (DUT) through a front panel of the integrated HIL system;
decoding, by the microcontroller unit, the test parameters for determining a test functionality to be performed on the DUT;
performing, by the microcontroller unit, the test functionality on the DUT using one of a plurality of hardware abstraction layers, comprised in an automated test application interface of the microcontroller unit, and generate a test outcome corresponding to the test functionality; and
output, by the microcontroller unit, the test outcome on a display interface of the front panel.

8. The method of claim 7, further comprises configuring a plurality of test modules in the microcontroller unit,
wherein the plurality of test modules includes at least one of a DUT-specific evaluation board, an ethernet module, a Controller Area Network (CAN) module, an Analog-to-Digital Converter (ADC) module, a Digital-to-Analog Converter (DAC) module, a Pulse Width Modulation (PWM) module, a resistor bank module, Local Interconnect Network (LIN) module, a relay module and a digital I/O module in the,
wherein the plurality of hardware abstraction layers of the automated test application interface is configured to correspond to the plurality of test modules.

9. The method of claim 8, wherein the plurality of hardware abstraction layers communicates with corresponding plurality of test modules through an abstract interface configured in the automated test application interface.

10. The method of claim 7, wherein the test outcome comprises a plurality of log files generated while performing the test functionality and an indication of completion of testing of the DUT.

11. A non-transitory computer-readable medium storing computer-executable instructions for testing hardware devices using an integrated Hardware-In-the-Loop (HIL) system, comprising:
receiving test parameters required for testing a Device Under Test (DUT) through a front panel of the integrated HIL system;
decoding the test parameters for determining a test functionality to be performed on the DUT;
performing the test functionality on the DUT using one of a plurality of hardware abstraction layers, comprised in an automated test application interface of the microcontroller unit, and generate a test outcome corresponding to the test functionality; and
outputting the test outcome on a display interface of the front panel.

12. The non-transitory computer-readable medium of claim 11, wherein the computer-executable instructions are further configured for configuring a plurality of test modules in the microcontroller unit,
wherein the plurality of test modules includes at least one of a DUT-specific evaluation board, an ethernet module, a Controller Area Network (CAN) module, an Analog-to-Digital Converter (ADC) module, a Digital-to-Analog Converter (DAC) module, a Pulse Width Modulation (PWM) module, a resistor bank module, Local Interconnect Network (LIN) module, a relay module and a digital I/O module in the,
wherein the plurality of hardware abstraction layers of the automated test application interface is configured to correspond to the plurality of test modules.

13. The non-transitory computer-readable medium of claim 12, wherein the plurality of hardware abstraction layers communicates with corresponding plurality of test modules through an abstract interface configured in the automated test application interface.

14. The non-transitory computer-readable medium of claim 11, wherein the test outcome comprises a plurality of log files generated while performing the test functionality and an indication of completion of testing of the DUT.
